(19) United States
(12) Patent Application Publication
(10) Pub. No.: US 2021/0288196 A1
(43) Pub. Date: Sep. 16, 2021

(54) SOLAR CELL AND METHOD FOR MANUFACTURING SAME, AND SOLAR CELL MODULE

(71) Applicant: KANEKA CORPORATION, Osaka-shi, Osaka (JP)

(72) Inventors: Kunihiro NAKANO, Settsu-shi, Osaka (JP); Kunta YOSHIKAWA, Settsu-shi, Osaka (JP); Kenji YAMAMOTO, Settsu-shi, Osaka (JP)

(21) Appl. No.: 16/334,689

(22) PCT Filed: Jun. 9, 2017
(86) PCT No.: PCT/JP2017/021436

§ 371 Date: Mar. 19, 2019

(30) Foreign Application Priority Data
Sep. 20, 2016 (JP) 2016-183302

(51) Int. Cl. H01L 31/048; H01L 31/0392; H01L 31/18

(52) U.S. Cl. CPC H01L 31/048; H01L 31/186; H01L 31/03921

(57) ABSTRACT

A solar cell includes a semiconductor substrate having a photoelectric conversion section, a first electrode, and a second electrode. The semiconductor substrate has a thickness of 70 μm or more and 200 μm or less. A chipping mark is present on an edge of at least one principal surface of the semiconductor substrate. The maximum length of the chipping mark along a side of the semiconductor substrate is 45 μm or less. The semiconductor substrate does not have a scribe mark due to laser irradiation. The solar cell can suppress a reduction in the fill factor.

### CROSS REFERENCE TO RELATED APPLICATION

This application claims the benefit of Japanese Patent Application No. 2016-183302, filed on Sep. 20, 2016, in the JPO (Japanese Patent Office). Further, this application is the National Phase application of International Application No. PCT/JP2017/021436, filed Jun. 9, 2017, which designates the United States and was published in Japan. Both of the priority documents are hereby incorporated by reference in their entireties.

### TECHNICAL FIELD

The embodiment relates to a solar cell, a method for manufacturing the solar cell, and a solar module including the solar cell.

### BACKGROUND ART

When solar cells are used in a power generation system, several solar cells are connected to form a module, namely a solar cell module. The solar cell module can be produced by forming a photoelectric conversion section on a semiconductor substrate, then cleaving the semiconductor substrate into single solar cells of various sizes, and connecting two or more of the single solar cells. Therefore, the cleavage of solar cells is an important process in the production process of the solar cell module.

The cleavage of solar cells has been conventionally performed by a laser dicing method using a laser or a mechanical dicing method using a dicing saw (see, e.g., Patent Documents 1 and 2).

### PRIOR ART DOCUMENTS

### Patent Documents

Patent Document 1: JP 2006-286673 A
Patent Document 2: JP 2012-114388 A

### DISCLOSURE OF INVENTION

### Problem to be Solved by the Invention

However, in the laser dicing method, it is inevitable that the heat of the laser will damage the semiconductor substrate. Moreover, in the mechanical dicing method, the fill factor of a solar cell will be reduced due to, e.g., a short circuit of a pn junction, as taught by Patent Document 1.

Patent Document 2 uses the mechanical dicing method to cut a substrate for a double-sided electrode type solar cell. However, Patent Document 2 is silent about the fill factor of a solar cell and is unclear as to whether a reduction in the fill factor can be suppressed or not.

As described above, it may be difficult to suppress a reduction in the fill factor of a solar cell with the mechanical dicing method. For this reason, the mechanical dicing method has not been put to practical use for the cleavage of solar cells.

The embodiment has solved the above problems and provides a solar cell with improved fill factor, a method for manufacturing the solar cell, and a solar cell module including the solar cell.

### Means for Solving Problem

A solar cell of the embodiment includes a semiconductor substrate. The semiconductor substrate has a thickness of 70 μm or more and 200 μm or less. A chipping mark is present on an edge of at least one principal surface of the semiconductor substrate. A maximum length of the chipping mark along a side of the semiconductor substrate is 45 μm or less.

A solar cell module of the embodiment includes a plurality of the solar cells of the embodiment.

A method for manufacturing a solar cell of the embodiment includes a dicing process of cleaving a semiconductor substrate with a dicing saw having a blade. The semiconductor substrate has a thickness of 70 μm or more and 200 μm or less. The dicing speed of the dicing saw is 10 mm/sec or more and 100 mm/sec or less. The blade is provided with diamond abrasive grains. The diamond abrasive grains have a grain size of #1000 or less in accordance with the Japan Industrial Standards (JIS) R 6001 (1998).

### Effects of the Invention

The embodiment can provide a solar cell and a solar cell module with improved fill factor.

### BRIEF DESCRIPTION OF DRAWINGS

FIG. 1 is a schematic cross-sectional view showing an example of a solar cell of an embodiment.

FIG. 2A to FIG. 2D are a schematic view showing an example of a manufacturing process of a solar cell of an embodiment.

FIG. 3 is a diagram showing the relationship between a dicing speed and an open circuit voltage.

FIG. 4 is a diagram showing the relationship between a dicing speed and a fill factor.

FIG. 5 is a diagram showing the relationship between the grain size of abrasive grains of a blade and an open circuit voltage.

FIG. 6 is a diagram showing the relationship between the grain size of abrasive grains of a blade and a fill factor.

FIG. 7 is a diagram showing the relationship between the maximum length of a chipping mark and an open circuit voltage.

FIG. 8 is a diagram showing the relationship between the maximum length of a chipping mark and a fill factor.

### DESCRIPTION OF THE INVENTION

The present inventors conducted various studies on the causes of reducing the fill factor of a solar cell when the solar cell was cleaved by the mechanical dicing method. As a result, the present inventors found out that the size of a chipping mark made on the edge of a semiconductor substrate during dicing would affect the fill factor of the solar cell. Thus, the present inventors have completed the embodiment. In the context of the embodiment, the chipping mark means a missing part that occurs on the surface of the semiconductor substrate due to mechanical dicing. Hereinafter, embodiments will be described.

(Solar Cell)

First, an embodiment of a solar cell will be described. The solar cell of this embodiment includes a semiconductor substrate. The semiconductor substrate has a thickness of 70 μm or more and 200 μm or less. A chipping mark is present on an edge of at least one principal surface of the semiconductor substrate. The maximum length of the chipping mark along a side of the semiconductor substrate is 45 μm or less.

Since the size of the chipping mark is within the above range, it may be possible to suppress the occurrence of a leakage current caused by the chipping mark and thus to suppress a reduction in the fill factor of the solar cell.

The chipping mark is made when the semiconductor substrate is cleaved by the mechanical dicing method. The conditions of the mechanical dicing method are optimized so that the size of the chipping mark can be set within the above range. Moreover, the semiconductor substrate is not cleaved by the laser dicing method, and therefore does not have a scribe mark due to laser irradiation.

The chipping mark may consist of not only a single missing part, but also a group of missing parts gathered together. Accordingly, when the chipping mark is a single missing part, the maximum length of the chipping mark along the side of the semiconductor substrate is the maximum length of the single missing part. When the chipping mark is a group of missing parts, the maximum length of the chipping mark is the maximum length of the missing parts that are strung together. The lower limit of the maximum length of the chipping mark is not particularly limited and may be about 0.1 μm in the general mechanical dicing method.

The maximum length of the chipping mark may be measured by observing the semiconductor substrate with, e.g., a scanning electron microscope.

The thickness of the semiconductor substrate is set to 70 μm or more and 200 μm or less. In this regard, the semiconductor substrate differs from a semiconductor chip substrate that has a thickness of more than 500 μm and is used for an integrated circuit or the like.

In the solar cell, a photoelectric conversion section, a first electrode, and a second electrode are formed on the semiconductor substrate. The solar cell may be a double-sided electrode type solar cell in which the first electrode is disposed on the first principal surface of the semiconductor substrate and the second electrode is disposed on the second principal surface of the semiconductor substrate. Alternatively, the solar cell may be a back contact type solar cell in which the first electrode and the second electrode are disposed on the same principal surface of the semiconductor substrate.

The semiconductor substrate may be either a monocrystalline silicon substrate or a polycrystalline silicon substrate. The use of the monocrystalline silicon substrate can achieve high photoelectric conversion efficiency. The use of the polycrystalline silicon substrate can produce a solar cell at a lower cost.

Next, the solar cell of this embodiment will be described with reference to the drawings. The solar cell of this embodiment is preferably a heterojunction-type solar cell because of its high photoelectric conversion efficiency. The following embodiments describe the heterojunction-type solar cell. However, the solar cell of the embodiment is not limited to the heterojunction-type solar cell and may be, e.g., a homojunction-type solar cell.

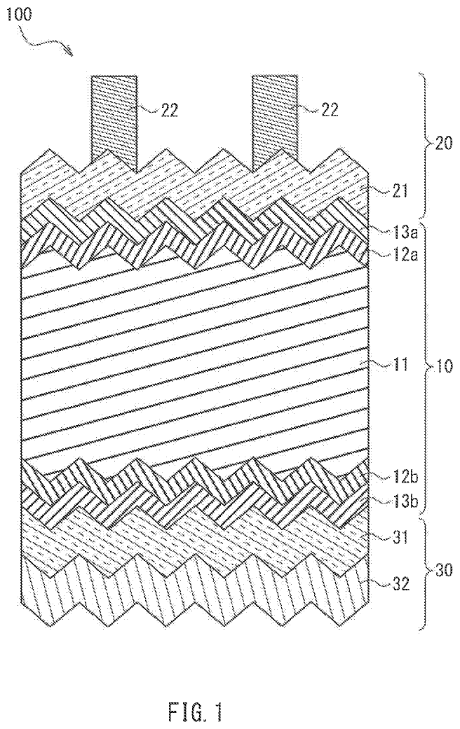

FIG. 1 is a schematic cross-sectional view showing an example of the solar cell of this embodiment. In FIG. 1, a solar cell 100 includes a photoelectric conversion section 10, and a first electrode 20 and a second electrode 30 that are located on both sides of the photoelectric conversion section 10.

<Photoelectric Conversion Section>

In the photoelectric conversion section 10, a semiconductor substrate 11 (also referred to simply as a “substrate 11” in the following) has a first principal surface (also referred to as a “surface” in the following) on a light incident side and a second principal surface (also referred to as a “back surface” in the following) on the opposite side to the light incident side of the substrate 11. An intrinsic silicon thin film 12a and a conductive silicon thin film 13a are formed in this order on the first principal surface. Moreover, an intrinsic silicon thin film 12b and a conductive silicon thin film 13b are formed in this order on the second principal surface.

The substrate 11 is a one conductivity type monocrystalline silicon substrate. The monocrystalline silicon substrate generally has two types: n-type containing atoms (e.g., phosphorus) for introducing electrons into silicon atoms; and p-type containing atoms (e.g., boron) for introducing holes into silicon atoms. In the context of the embodiment, the “one conductivity type” means one of n-type and p-type. That is, the substrate 11 is either an n-type monocrystalline silicon substrate or a p-type monocrystalline silicon substrate. The substrate 11 is preferably the n-type monocrystalline silicon substrate.

The substrate 11 preferably has a textured structure (uneven structure) on the surface and the back surface. With this configuration, the photoelectric conversion section 10 also has a textured structure because the substrate 11 serves as a base for the photoelectric conversion section 10. Thus, the solar cell 100 is able to trap incident light inside the photoelectric conversion section 10 and can improve power generation efficiency.

It is preferable that there is no chipping mark on the substrate 11. However, even if a chipping mark is made when the substrate 11 is cleaved by the mechanical dicing method, the maximum length of the chipping mark along the side of the substrate 11 is set to 45 μm or less, preferably 25 μm or less, and more preferably 10 μm or less. This allows the chipping mark to be relatively small and can suppress the occurrence of a leakage current between the surface and the back surface of the substrate 11 caused by the chipping mark. Consequently, it is possible to suppress a reduction in the fill factor of the solar cell.

A plasma CVD method is preferably used to form the silicon thin films 12a, 13a, 12b, and 13b. The conductive silicon thin films 13a, 13b are one conductivity type or reverse conductivity type silicon thin films. In the context of the embodiment, the “reverse conductivity type” means a conductivity type that is different from the “one conductivity type.” For example, when the “one conductivity type” is n-type, the “reverse conductivity type” is p-type. In this embodiment, the conductive silicon thin film 13a is a reverse conductivity type silicon thin film and the conductive silicon thin film 13b is a one conductivity type silicon thin film. In general, the silicon thin films 12a, 13a, 12b, and 13b are preferably formed as amorphous silicon thin films.

In this embodiment, the conductive silicon thin film 13a is a p-type amorphous silicon thin film and the conductive silicon thin film 13b is an n-type amorphous silicon thin film. The intrinsic silicon thin films 12a, 12b are preferably i-type hydrogenated amorphous silicon composed of silicon and hydrogen.

<First Electrode and Second Electrode>

The first electrode 20 includes a first transparent electrode layer 21 and a first collector 22. The first transparent electrode layer 21 and the first collector 22 are formed in this order on the conductive silicon thin film 13a of the photoelectric conversion section 10. The second electrode 30 includes a second transparent electrode layer 31 and a second collector 32. The second transparent electrode layer 31 and the second collector 32 are formed in this order on the conductive silicon thin film 13b of the photoelectric conversion section 10.

[Transparent Electrode Layer]

The first transparent electrode layer 21 and the second transparent electrode layer 31 preferably contain a conductive oxide as the main component. Examples of the conductive oxide include zinc oxide, indium oxide, and tin oxide. These oxides may be used individually or in combination. From the viewpoint of conductivity optical properties, and long-term reliability, an indium-based oxide is preferred, which contains an indium oxide as the main component. In the context of the embodiment, the “main component” means that the content of the component is more than 50% by mass, preferably 70% by mass or more, and more preferably 85% by mass or more. The conductive oxide as the main component of the transparent electrode layers 21, 31 preferably contains at least one element of e.g., Sn, W, As, Zn, Ge, Ca, Si, and C as a dopant, depending on the usage situation. Among them, indium tin oxide (ITO) containing Sn as a dopant is particularly preferred.

The first transparent electrode layer 21 and the second transparent electrode layer 31 may have a single-layer structure or a laminated structure of multiple layers. From the viewpoint of transparency, conductivity, and low light reflection, the thickness of the first transparent electrode layer 21 on the light incident side is preferably 10 nm or more and 140 nm or less. When the thickness of the first transparent electrode layer 21 is 10 nm or more, necessary conductivity can be imparted because the first transparent electrode layer 21 functions to transport carriers to the first collector 22. When the thickness of the first transparent electrode layer 21 is 140 nm or less, the light absorption loss in the first transparent electrode layer 21 can be reduced, thereby suppressing a reduction in the photoelectric conversion efficiency due to low light transmittance. Moreover, an increase in the carrier concentration in the first transparent electrode layer 21 can be prevented by controlling the thickness of the first transparent electrode layer 21 within the above range. This also can suppress a reduction in the photoelectric conversion efficiency due to low light transmittance in the infrared region. On the other hand, the thickness of the second transparent electrode layer 31 on the back side is not particularly limited and may be the same as that of the first transparent electrode layer 21.

The first transparent electrode layer 21 and the second transparent electrode layer 31 may be formed by any method, including, e.g., a sputtering method.

[Collector]

The first collector 22 on the light incident side is preferably formed into, e.g., a comb-like pattern having a light transmission section. If the first collector 22 on the light incident side does not have a light transmission section, a light capture amount will be reduced with increasing a light shielding loss, which leads to a decrease in short circuit current. The first collector 22 can be produced by any known technique, including, e.g., ink jet, screen printing, wire bonding, spraying, vacuum deposition, sputtering, and plating. In particular, plating is preferred because it can provide thinner lines.

The second collector 32 on the back side is preferably formed to cover the entire surface of the second transparent electrode layer 31 in order to improve the light reflection efficiency. It is desirable that the second collector 32 is made of a material that has a high reflectance to light in the near infrared to infrared region, high conductivity, and high chemical stability. The material with these properties may be, e.g., silver or aluminum. The second collector 32 can be produced by any method, including, e.g., a physical vapor phase deposition method such as sputtering or vacuum deposition, a printing method such as screen printing, and a plating method. The second collector 32 is used as an electrode on the back side, and therefore may be formed as a grid electrode.

(Solar Cell Module)

Next, an embodiment of a solar cell module will be described. The solar cell module of this embodiment includes a plurality of the solar cells of the above embodiment. The solar cell module including the solar cells of the above embodiment can suppress a reduction in the fill factor of the individual solar cells. Specifically, each of the solar cells of the solar cell module has a relatively small chipping mark, whose maximum length along the side of the semiconductor substrate is 45 μm or less, so that the occurrence of a leakage current caused by the chipping mark can be suppressed. Consequently, it is possible to suppress a reduction in the fill factor of the individual solar cells.

(Method for Manufacturing Solar Cell)

Next, an embodiment of a method for manufacturing a solar cell will be described. The method for manufacturing a solar cell of this embodiment includes a dicing process of cleaving a semiconductor substrate with a dicing saw having a blade. The semiconductor substrate has a thickness of 70 μm or more and 200 μm or less. The dicing speed of the dicing saw is 10 mm/sec or more and 100 mm/sec or less. The blade is provided with diamond abrasive grains. The diamond abrasive grains have a grain size of #1000 or less in accordance with the Japan Industrial Standards (JIS) R 6001 (1998).

In the manufacturing method of the solar cell, the maximum length of a chipping mark along the side of the semiconductor substrate can be set to 45 μm or less. Therefore, although the semiconductor substrate is cleaved by the mechanical dicing method, the occurrence of a leakage current caused by the chipping mark can be suppressed. Thus, the manufacturing method can suppress a reduction in the fill factor of the solar cell.

Since the dicing speed of the dicing saw is set to 10 mm/sec or more and 100 mm/sec or less, and the grain size of the diamond abrasive grains is set to #1000 or less in accordance with JIS R 6001 (1998), the chipping mark on the edge of the semiconductor substrate becomes smaller in size. The dicing speed of the dicing saw is more preferably 10 mm/sec or more and 50 mm/sec or less. The grain size of the diamond abrasive grains is more preferably #2000, and further preferably #4000 in accordance with JIS R 6001 (1998). In this case, the grain size based on JIS R 6001 (1998) indicates that the average particle diameter of particles is reduced as the number becomes larger. Thus, the relationship represented by average particle diameter #4000<average particle diameter #2000<average particle diameter #1000 is established.

In this embodiment, the measurement method of the grain size defined by JIS R 6001 (1998) complies with the electrical resistance test method defined by JIS R 6002 (1998).

Moreover, since the thickness of the semiconductor substrate is set to 70 μm or more and 200 μm or less, the semiconductor substrate is moderately bent when it is cleaved with the dicing saw in the dicing process. Thus, the manufacturing method can suppress the generation of cracks or gaps in the semiconductor substrate and reduce damage to the semiconductor substrate.

The blade is preferably a hub blade. The hub blade is a blade combined with a blade installation tool. When the dicing saw having the hub blade is used to divide the semiconductor substrate, vibration can be reduced during the rotation of the blade. Therefore, the semiconductor substrate is less likely to vibrate and also less likely to generate fine cracks. This can prevent a reduction in the photoelectric conversion efficiency of the solar cell.

The semiconductor substrate may be cleaved with the dicing saw by full-cutting, or half-cutting and bend-breaking. The dicing saw may cut into either the surface or back surface of the semiconductor substrate.

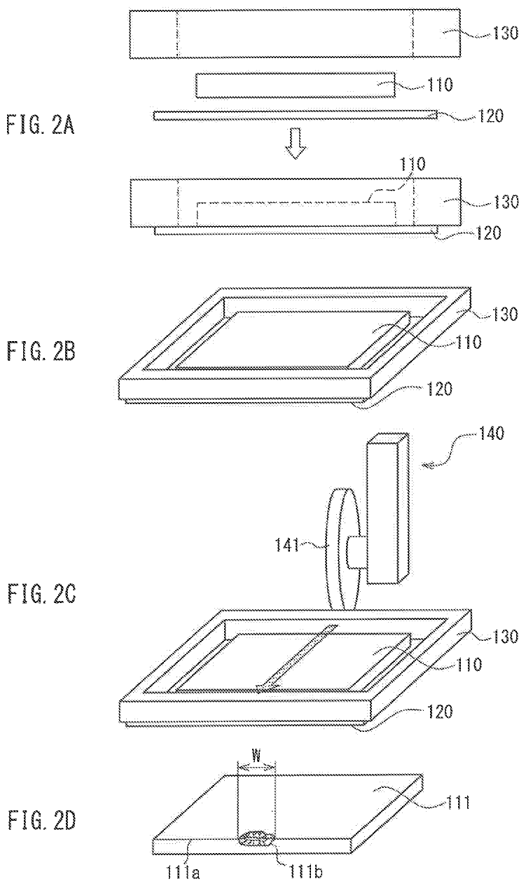

Next, an example of the manufacturing method of the solar cell of this embodiment will be described with reference to the drawings. FIG. 2A to FIG. 2D are a schematic view showing an example of the manufacturing process of the solar cell of this embodiment.

First, as shown in FIG. 2A, a semiconductor substrate 110 having a photoelectric conversion section, a first electrode, and a second electrode, an adhesive sheet 120, and a frame 130 surrounding the semiconductor substrate 110 are prepared. Subsequently, the semiconductor substrate 110 is bonded to the adhesive sheet 120, and then the adhesive sheet 120 is bonded and fixed to the frame 130. FIG. 2B is a perspective view showing a state in which the adhesive sheet 120 provided with the semiconductor substrate 110 is bonded and fixed to the frame 130.

Next, as shown in FIG. 2C, using a dicing blade 140 having a hub blade 141, the semiconductor substrate 110 is cleaved from the outside of the frame 130. In this case, the dicing blade 140 may cut into either the surface or back surface of the semiconductor substrate 110. Thereafter, the whole frame 130 is cleaned while the semiconductor substrate 110 is fixed, and then the semiconductor substrate is taken out of the frame 130. FIG. 2D show a state in which a cleaved semiconductor substrate 111 has been taken out of the frame 130. A chipping mark 111b is made on a side 111a of the semiconductor substrate 111. The maximum length W of the chipping mark 111b along the side 111a of the semiconductor substrate 111 is 45 μm or less.

The cleaved semiconductor substrate 111 may be used as a solar cell, and a plurality of the semiconductor substrates 111 are connected to form a solar cell module.

### EXAMPLES

Hereinafter, the embodiment will be described in detail by way of examples. However, the embodiment is not limited to the following examples. In this specification, the thickness of a semiconductor substrate with a textured structure and the thickness of a thin film formed on the semiconductor substrate represent the distance measured from the bottom of the concave parts or the top of the convex parts in the textured structure along the thickness direction of the semiconductor substrate.

### Example 1

As a one conductivity type monocrystalline silicon substrate, an n-type monocrystalline silicon wafer was used, which had the plane of incidence in the direction of (100) and a thickness of 200 μm. This silicon wafer was immersed in 2% by mass of a HF aqueous solution for 3 minutes so that the silicon oxide film on the surface was removed. Then, the silicon wafer was rinsed two times with ultrapure water. A mixed aqueous solution containing 5% by mass of KOH and 15% by mass of isopropyl alcohol was maintained at 70° C. The above silicon wafer was immersed in the mixed aqueous solution for 15 minutes so that the surface of the wafer was etched to form a texture. Then, the wafer was rinsed two times with ultrapure water. At this stage, the surface of the wafer was observed with an atomic force microscope (AFM) manufactured by Pacific Nanotechnology Inc. The observation confirmed that the etching on the surface of the wafer proceeded most rapidly, and the (111) plane was exposed to form a pyramidal texture.

Next, the etched wafer was set into a CVD apparatus. Then, a first i-type amorphous silicon layer (i.e., the intrinsic silicon thin film) with a thickness of 5 nm was formed on the light incident side of the wafer. The first i-type amorphous silicon layer was formed under the following conditions: the substrate temperature was 150° C.; the pressure was 120 Pa; the SiH₄/H₂ flow rate ratio was 3/10; and the input power density was 0.011 W/cm².

Then, a p-type amorphous silicon layer (i.e., the reverse conductivity type silicon thin film) with a thickness of 7 nm was formed on the first i-type amorphous silicon layer. The p-type amorphous silicon layer was formed under the following conditions: the substrate temperature was 150° C.; the pressure was 60 Pa; the SiH₄/B₂H₆ flow rate ratio was 1/3; and the input power density was 0.01 W/cm². The B₂H₆ gas flow rate was the flow rate of diluent gas obtained by diluting the B₂H₆ gas with H₂ until the B₂H₆ concentration was 5000 ppm.

Next, a second i-type amorphous silicon layer (i.e., the intrinsic silicon thin film) with a thickness of 6 nm was formed on the back side of the wafer. The second i-type amorphous silicon layer was formed under the same conditions as the first i-type amorphous silicon layer. Then, an n-type amorphous silicon layer (i.e., the one conductivity type silicon thin film) with a thickness of 4 nm was formed on the second i-type amorphous silicon layer. The n-type amorphous silicon layer was formed under the following conditions: the substrate temperature was 150° C.; the pressure was 60 Pa; the SiH₄/PH₃ flow rate ratio was 1/2; and the input power density was 0.01 W/cm². The PH₃ gas flow rate was the flow rate of diluent gas obtained by diluting the PH₃ gas with H₂ until the PH₃ concentration was 5000 ppm.

Next, ITO (i.e., the first transparent electrode layer) with a thickness of 80 nm was formed on the p-type amorphous silicon layer by a sputtering device. The ITO was formed under the following conditions: indium tin oxide was used as a target; the substrate temperature was room temperature; the pressure was 0.2 Pa in an argon atmosphere; and the applied power density was 0.5 W/cm². Subsequently, ITO (i.e., the second transparent electrode layer) with a thickness of 80 nm was formed on the n-type amorphous silicon layer under the same conditions as described above.

Next, a silver paste was applied on the first transparent electrode layer by screen printing to form a comb-like first collector. Then, silver with a thickness of 500 nm was formed on the second transparent electrode layer by sputtering to form a second collector that covered the entire surface of the second transparent electrode layer.

Next, the laminated body thus produced was annealed at 190° C. for 1 hour, resulting in a solar cell before cleavage.

Then, the solar cell before cleavage was subjected to a dicing process in which the semiconductor substrate was fully cut from the surface with a dicing machine “DAD 3350” manufactured by DISCO Corporation. Thus, the above solar cell was cleaved into solar cells of Example 1. The dicing blade was a hub blade. The grain size of the diamond abrasive grains of the dicing blade was #4000 in accordance with JIS R 6001 (1998). The dicing speed was 10 mm/sec.

### Example 2

Solar cells of Example 2 were manufactured in the same manner as Example 1 except that the dicing speed was changed to 50 mm/sec.

### Example 3

Solar cells of Example 3 were manufactured in the same manner as Example 1 except that the dicing speed was changed to 100 mm/sec.

### Comparative Example 1

A solar cell before cleavage was produced in the same manner as Example 1. Then, laser scribe processing was performed on the back surface of the solar cell before cleavage using the third-order harmonic (wavelength: 355 nm) of a YAG laser. Thus, the above solar cell was cleaved by bend-breaking into solar cells of Comparative Example 1.

### Example 4

Solar cells of Example 4 were manufactured in the same manner as Example 1 except that the grain size of the diamond abrasive grains was changed to #2000 in accordance with JIS R 6001 (1998), and the dicing speed was changed to 100 mm/sec.

### Example 5

Solar cells of Example 5 were manufactured in the same manner as Example 1 except that the grain size of the diamond abrasive grains was changed to #1000 in accordance with JIS R 6001 (1998), and the dicing speed was changed to 100 mm/sec.

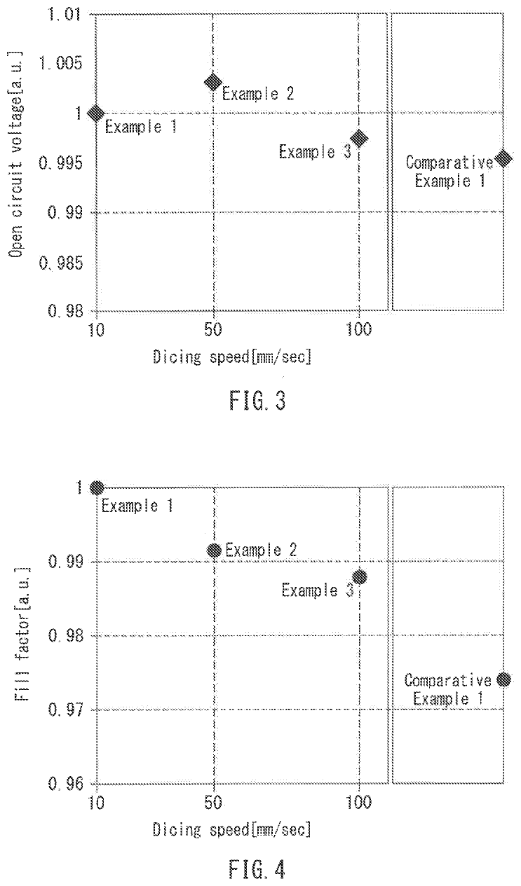

The photoelectric conversion properties of the solar cells of Examples 1 to 5 and Comparative Example 1 that were manufactured in the above manner were evaluated by measuring the open circuit voltage (Voc) and the fill factor (FF). FIGS. 3 to 6 show the results.

FIG. 3 is a diagram showing the relationship between the dicing speed and the open circuit voltage. FIG. 3 also shows the open circuit voltage in Comparative Example 1 using the laser dicing method. It is evident from FIG. 3 that the dicing speed has a small effect on the open circuit voltage. Comparing Examples 1 to 3 using the mechanical dicing method and Comparative Example 1 using the laser dicing method, it is confirmed that the open circuit voltage obtained by the mechanical dicing method is equal to or higher than that obtained by the laser dicing method.

FIG. 4 is a diagram showing the relationship between the dicing speed and the fill factor. FIG. 4 also shows the fill factor in Comparative Example 1 using the laser dicing method. It is evident from FIG. 4 that the dicing speed has a significant effect on the fill factor, and the fill factor is improved with decreasing the dicing speed. Comparing Examples 1 to 3 using the mechanical dicing method and Comparative Example 1 using the laser dicing method, it is confirmed that the fill factor obtained by the mechanical dicing method is much more improved than that obtained by the laser dicing method. These results disprove the common technical knowledge that the conventional mechanical dicing method would cause the occurrence of a leakage current to reduce the fill factor. Thus, the above results cannot be expected from the conventional common technical knowledge.

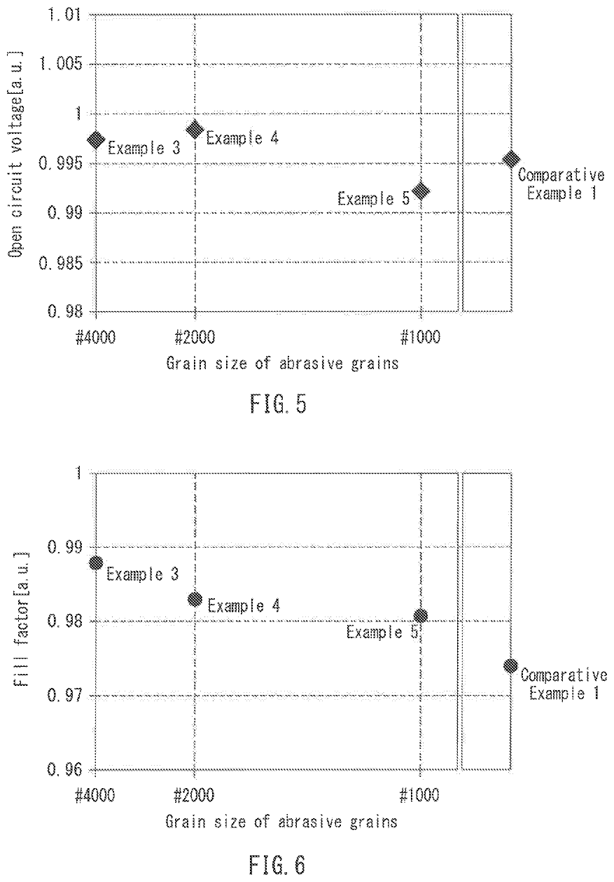

FIG. 5 is a diagram showing the relationship between the grain size of the abrasive grains of the blade and the open circuit voltage. FIG. 5 also shows the open circuit voltage in Comparative Example 1 using the laser dicing method. It is evident from FIG. 5 that the grain size of the abrasive grains of the blade has a small effect on the open circuit voltage.

FIG. 6 is a diagram showing the relationship between the grain size of the abrasive grains of the blade and the fill factor. FIG. 6 also shows fill factor in Comparative Example 1 using the laser dicing method. It is evident from FIG. 6 that the fill factor is improved with decreasing the grain size of the abrasive grains of the blade.

Next, the edge of each of the cleaved solar cells in Examples 1 to 5 and Comparative Example 1 were observed with a scanning electron microscope to measure the maximum length of a chipping mark along the side of the semiconductor substrate. When a plurality of chipping marks were present, the maximum length of these chipping marks was measured. Consequently, the chipping mark was observed in Examples 1 to 5, but no chipping mark was observed in Comparative Example 1. Table 1 shows the measurement results along with the dicing speed and the grain size of the diamond abrasive grains.

TABLE 1

| | Maximum length of | Dicing speed | Grain size of diamond |
|---|---|---|---|
| | chipping mark (μm) | (mm/sec) | abrasive grains |
| Example 1 | 7 | 10 | #4000 |
| Example 2 | 14 | 50 | #4000 |
| Example 3 | 24 | 100 | #4000 |
| Example 4 | 32 | 100 | #2000 |
| Example 5 | 43 | 100 | #1000 |
| Comparative | — | — | — |
| Example 1 | | | |

As can be seen from Table 1, when the dicing speed is 10 mm/sec or more and 100 mm/sec or less, and the grain size of the diamond abrasive grains is #1000 or less, the maximum length of the chipping mark can be controlled to 45 μm or less.

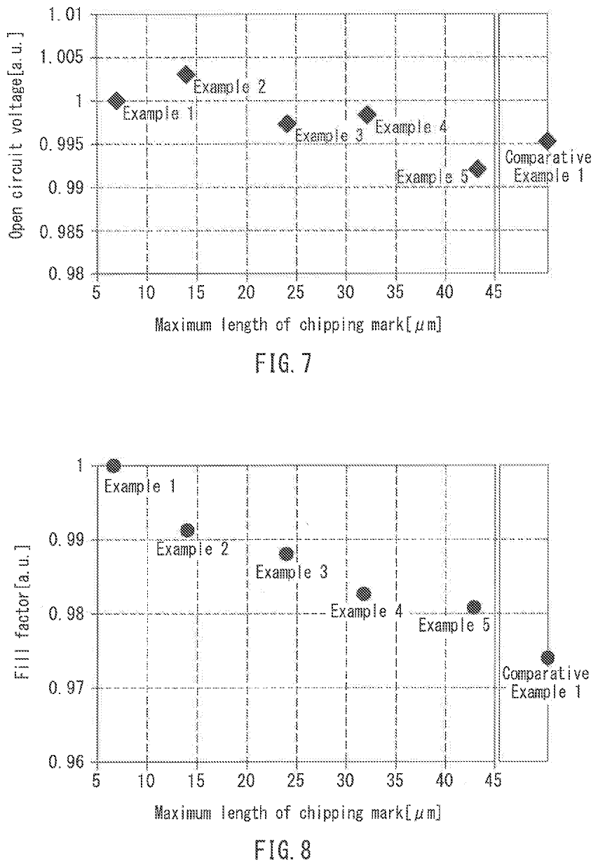

Based on the above results, FIG. 7 shows the relationship between the maximum length of the chipping mark and the open circuit voltage and FIG. 8 shows the relationship between the maximum length of the chipping mark and the fill factor. For comparison purposes, FIGS. 7 and 8 also show the open circuit voltage and the fill factor in Comparative Example 1 using the laser dicing method, respectively.

It is evident from FIG. 7 that the size of the chipping mark has a small effect on the open circuit voltage. Moreover, it is evident from FIG. 8 that the size of the chipping mark has a significant effect on the fill factor, and the fill factor is improved with decreasing the size of the chipping mark. It is also evident from FIG. 8 that the fill factor in Examples 1 to 5 is much more improved than that in Comparative Example 1, since the maximum length of the chipping mark is controlled to 45 μm or less in Examples 1 to 5.

In Examples 1 to 5, the photoelectric conversion section, the first electrode, and the second electrode were formed on the semiconductor substrate, and then this semiconductor substrate was cleaved. However, the embodiment is not limited thereto. For example, the photoelectric conversion section may be formed on the semiconductor substrate, then this semiconductor substrate may be cleaved, and the first electrode and the second electrode may be formed on the cleaved semiconductor substrate. Alternatively, the semiconductor substrate may be cleaved, and then the photoelectric conversion section, the first electrode, and the second electrode may be formed on the cleaved semiconductor substrate. Even if the semiconductor substrate is cleaved in the order listed above, the manufacturing method of the solar cell can suppress the occurrence of a leakage current caused by the chipping mark on the semiconductor substrate, and thus can suppress a reduction in the fill factor of the solar cell.

### DESCRIPTION OF REFERENCE NUMERALS

10 Photoelectric conversion section
11 Semiconductor substrate
12a, 12b Intrinsic silicon thin film
13a, 13b Conductive silicon thin film
20 Frist electrode
21 First transparent electrode layer
22 First collector
30 Second electrode
31 Second transparent electrode layer
32 Second collector
100 Solar cell
110 Semiconductor substrate
120 Adhesive sheet
130 Frame
140 Dicing blade
141 Hub blade
111 Semiconductor substrate
111a Side
111b Chipping mark

1. A solar cell comprising a semiconductor substrate,
wherein the semiconductor substrate has a thickness of 70 μm or more and 200 μm or less,
a chipping mark is present on an edge of at least one principal surface of the semiconductor substrate, and
a maximum length of the chipping mark along a side of the semiconductor substrate is 45 μm or less.

2. The solar cell according to claim 1, wherein the semiconductor substrate does not have a scribe mark due to laser irradiation.

3. The solar cell according to claim 1, wherein a photoelectric conversion section, a first electrode, and a second electrode are formed on the semiconductor substrate, and
the first electrode is disposed on a first principal surface of the semiconductor substrate and the second electrode is disposed on a second principal surface of the semiconductor substrate.

4. The solar cell according to claim 1, wherein a photoelectric conversion section, a first electrode, and a second electrode are formed on the semiconductor substrate, and
the first electrode and the second electrode are disposed on the same principal surface of the semiconductor substrate.

5. The solar cell according to claim 1, wherein the semiconductor substrate is either a monocrystalline silicon substrate or a polycrystalline silicon substrate.

6. A solar cell module comprising a plurality of the solar cells according to claim 1.

7. A method for manufacturing a solar cell, comprising:
a dicing process of cleaving a semiconductor substrate with a dicing saw having a blade,
wherein the semiconductor substrate has a thickness of 70 μm or more and 200 μm or less,
a dicing speed of the dicing saw is 10 mm/sec or more and 100 mm/sec or less,
the blade is provided with diamond abrasive grains, and
the diamond abrasive grains have a grain size of #1000 or less in accordance with the Japan Industrial Standards (JIS) R 6001 (1998).

8. The method according to claim 7, wherein the blade is a hub blade.

9. The method according to claim 7, wherein the semiconductor substrate is cleaved with the dicing saw by full-cutting.

10. The method according to claim 7, wherein the semiconductor substrate is cleaved with the dicing saw by half-cutting and bend-breaking.
